(19) United States
(12) Patent Application Publication
(10) Pub. No.: US 2011/0233636 A1
(43) Pub. Date: Sep. 29, 2011

(54) Semiconductor Memory Device and Method of Manufacturing the Same

(76) Inventors: Byung-kyu Cho, Seoul (KR); Kwang-soo Seol, Yongin-si (KR); Sung-hoi Hur, Seoul (KR); Jung-dal Choi, Hwaseong-si (KR)

(21) Appl. No.: 13/050,320

(22) Filed: Mar. 17, 2011

(30) Foreign Application Priority Data
Mar. 23, 2010 (KR) 10-2010-0025879

(51) Int. Cl. H01L 29/78

(52) U.S. Cl. 257/314; 257/E29.255

(57) ABSTRACT

A non-volatile memory device and a method of manufacturing the non-volatile memory device are disclosed. The non-volatile memory device includes a substrate, at least two gate structures on the substrate, and at least one impurity region in portions of the substrate between the at least two gate structures. The center of the at least one impurity region is horizontally offset from the center of a region between the at least two gate structures.

### CROSS-REFERENCE TO RELATED APPLICATIONS

This application claims the benefit of Korean Patent Application No. 10-2010-0025879, filed on Mar. 23, 2010, in the Korean Intellectual Property Office, the disclosure of which is incorporated herein in its entirety by reference.

### BACKGROUND

The inventive concept relates to a semiconductor device, and more particularly, to a non-volatile semiconductor memory device and a method of manufacturing the same.

Size reduction and increased data processing capacity are demanded of non-volatile memory devices. Therefore, it is desirable to increase the integration of semiconductor devices constituting such non-volatile memory devices. To do so, the design rule with respect to components of a semiconductor device may be reduced. In particular, in a semiconductor device requiring a large number of transistors, the length of a gate in a transistor, which is the standard for determining the design rule, may be reduced. However, reducing the design rule for semiconductor devices may lead to unwanted electrical effects in the device.

### SUMMARY

According to an aspect of the inventive concept, a non-volatile memory device includes a substrate, at least two gate structures on the substrate, and at least one impurity region at least partially disposed in portions of the substrate between the at least two gate structures. The center of the at least one impurity region is horizontally offset from the center of a region between the at least two gate structures.

The at least two gate structures include a first gate structure and a second gate structure. The first gate structure is configured to receive a programming voltage for performing a programming operation with respect to the non-volatile memory device before the programming voltage is applied to the second gate structure. The center of the at least one impurity region may be closer to the second gate structure than the first gate structure. The at least one impurity region may be at least partially disposed in portions of the substrate below the second gate structure.

The device may include a plurality of gate structures arranged in a row on the substrate, the at least one impurity region may include a plurality of impurity regions, and each of the plurality of impurity regions may be between two adjacent gate structures of the plurality of gate structures. The non-volatile memory device may further include a first selection transistor, which is on the substrate and adjacent to the first gate structure from among the plurality of gate structures and is connected to a bit line, and a second selection transistor, which is on the substrate and adjacent to the N^{th} gate structure from among the plurality of gate structures and is connected to a common source line, wherein N may be an integer equal to or greater than 2. The center of each of the plurality of impurity regions may be horizontally offset toward one of two gate structures adjacent to each of the impurity regions, e.g., the one closer to the second selection transistor. The center of each of the plurality of impurity regions may be horizontally offset toward one of two gate structures adjacent to each of the impurity regions, e.g., the one closer to the first selection transistor.

The at least one impurity region may have a shape that is symmetrical with respect to a vertical axis running through the center of the at least one impurity region. The at least one impurity region may have a shape that is asymmetrical with respect to the center of the at least one impurity region in some embodiments.

The at least two gate structures may each include a tunneling insulation layer on the substrate, a charge storage layer on the tunneling insulation layer, an interlayer insulation layer on the charge storage layer, and a gate electrode layer on the interlayer insulation layer.

According to another aspect of the inventive concept, there is provided a memory card including a memory unit including a non-volatile memory device according to the inventive concept, and a controller for controlling the memory unit.

According to another aspect of the inventive concept, there is provided an electronic system including a memory unit including a non-volatile memory device according to the inventive concept, a processor for communicating with the memory unit via a bus, and an input/output (I/O) device which communicates with the bus.

According to another aspect of the inventive concept, methods of manufacturing a non-volatile memory device include forming at least two gate structures on a substrate, and forming at least one impurity region in portions of the substrate between the at least two gate structures, wherein the at least one impurity region is formed in such a way that the center of the at least one impurity region is horizontally offset from the center of a region between the at least two gate structures.

The at least two gate structures may include a first gate structure and a second gate structure. A programming voltage for performing a programming operation with respect to the non-volatile memory device may be applied to the first gate structure before being applied to the second gate structure.

The formation of the at least one impurity region may include implanting an impurity in a direction inclined toward the first gate structure by a predetermined angle from a direction vertical to the substrate. The at least two gate structures may be used as a mask, and/or a separate implant mask may be used. The substrate may have a first conductivity type, the impurity may have a second conductivity type type, and the first conductivity type and the second conductivity type may be different from each other.

The formation of the at least one impurity region may include implanting an impurity having a first conductivity type in the substrate, and implanting an impurity having a second conductivity type in a direction inclined toward the second gate structure by a predetermined angle from a direction vertical to the substrate. The substrate may have the second conductivity type, and the first conductivity type and the second conductivity type may be different from each other.

The methods may further include forming a bit line contact plug, which is connected to a bit line, on the substrate. Forming the at least two gate structures may include forming on the substrate a plurality of first gate structures in a line at a first side of the bit line contact plug, and a plurality of second gate structures in a line at a second side of the bit line contact plug.

Forming the at least one impurity region may include forming a first mask layer on the plurality of first gate structures, implanting an impurity in a direction inclined toward the bit line contact plug by a predetermined angle from a direction vertical to the substrate, forming a second mask layer on the plurality of second gate structures, and implanting the impurity in a direction inclined toward the second gate structure by a predetermined angle from a direction vertical to the substrate. The substrate may have a first conductivity type, the impurity may have a second conductivity type, and the first conductivity type and the second conductivity type may be different from each other.

Forming the at least one impurity region may include implanting an impurity having a first conductivity type in the substrate, forming a first mask layer on the plurality of first gate structures, implanting an impurity having a second conductivity type in a direction inclined toward the opposite side from the bit line contact plug by a predetermined angle from a direction vertical to the substrate, forming a second mask layer on the plurality of second gate structures, and implanting the second conductivity type impurity in a direction inclined toward the opposite side from the bit line contact plug by a predetermined angle from a direction vertical to the substrate. The substrate may have the second conductivity type, and the first conductivity type and the second conductivity type may be different from each other.

A non-volatile memory device according to some further embodiments includes a semiconductor layer, a pair of gate structures on the semiconductor layer that define a region of the semiconductor layer between the pair of gate structures, and an impurity region in the semiconductor layer. The impurity region is at least partially disposed in the region of the semiconductor layer between the pair of gate structures and includes a source/drain region for both of the pair of gate structures. A center of the impurity region is horizontally offset from a center of the region of the semiconductor layer between the pair of gate structures.

The impurity region may be at least partially disposed beneath a first one of the pair of gate structures. The impurity region may not extend beneath a second one of the pair of gate structures.

The semiconductor layer may have a first conductivity type, and the region of the semiconductor layer between the pair of gate structures may include a first sub-region doped with second conductivity type impurities and a second sub-region that is free of second conductivity type impurities.

In some embodiments, the region of the semiconductor layer between the pair of gate structures includes a first sub-region doped with first and second conductivity type impurities and that may have a net conductivity of the second conductivity type and a second sub-region that is doped with both first and second conductivity type impurities and that may have a net conductivity of the first conductivity type.

### BRIEF DESCRIPTION OF THE DRAWINGS

Exemplary embodiments of the inventive concept will be more clearly understood from the following detailed description taken in conjunction with the accompanying drawings in which:

FIG. 1 is a block diagram of a non-volatile memory device according to an embodiment of the inventive concept;

FIG. 2 is a layout diagram of a portion of a memory cell array included in the non-volatile memory device of FIG. 1, according to an embodiment of the inventive concept;

FIG. 3 is a sectional view of a cell string according to an embodiment of the inventive concept, the sectional view obtained along a line I-I′ of FIG. 2;

FIG. 3A is a detailed cross sectional view of a portion of the cell string illustrated in FIG. 3.

FIG. 4 is a sectional view of a cell string according to another embodiment of the inventive concept, the sectional view obtained along a line I-I′ of FIG. 2;

FIG. 5 is a layout diagram of a portion of a memory cell array included in the non-volatile memory device of FIG. 1, according to another embodiment of the present invention;

FIG. 6 is a sectional view of a cell string according to an embodiment of the inventive concept, the sectional view obtained along a line II-II′ of FIG. 5;

FIG. 7 is a sectional view of a cell string according to another embodiment of the inventive concept, the sectional view obtained along a line II-II′ of FIG. 5;

FIGS. 8A through 8F are sectional views showing a method of manufacturing a non-volatile memory device, according to an embodiment of the inventive concept;

FIGS. 9A through 9F are sectional views showing a method of manufacturing a non-volatile memory device, according to another embodiment of the inventive concept;

FIG. 10 is a graph showing a simulated result of energy levels according to a location on a substrate in a general non-volatile memory device;

FIG. 11 is a graph showing a simulated result of energy levels according to a location on a substrate in a non-volatile memory device according to an embodiment of the inventive concept;

FIG. 12 is a schematic diagram of a card according to an embodiment of the inventive concept; and

FIG. 13 is a schematic view of an electronic system according to an embodiment of the inventive concept.

### DETAILED DESCRIPTION OF EMBODIMENTS

The inventive concept now will be described more fully hereinafter with reference to the accompanying drawings, in which illustrative embodiments of the inventive concept are shown. This inventive concept may, however, be embodied in many different forms and should not be construed as limited to the embodiments set forth herein; rather, these embodiments are provided so that this disclosure will be thorough and complete, and will fully convey the scope of the inventive concept to those skilled in the art.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. Like numbers refer to like elements throughout. As used herein, the term “and/or” includes any and all combinations of one or more of the associated listed items.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Embodiments of the inventive concept are described herein with reference to cross-section illustrations that are schematic illustrations of idealized embodiments (and intermediate structures) of the inventive concept. As such, variations from the shapes of the illustrations as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing. Like numbers refer to like elements throughout.

Due to the reduction of the design rule with respect to components of a semiconductor memory device, a gate line width of a transistor and distances between transistors are also reduced. For example, in the case where a plurality of gate structures are formed, due to a potential variation of a charge storage layer of a first gate structure, a potential of a charge storage layer of a second gate structure, which is adjacent to the first gate structure, may be changed, the potentials of a channel region and a drain region of the second gate structure may be changed, and an energy barrier between a source and a drain may increase. In some embodiments, adjacent gate structures may include gate structures on a same word line and an adjacent word line, and thus adjacent gate structures may include gate structures that are adjacent to each other diagonally. The increase of an energy barrier causes unexpected variation of the threshold voltage of a cell transistor, and thus the reliability of a semiconductor memory device may be reduced.

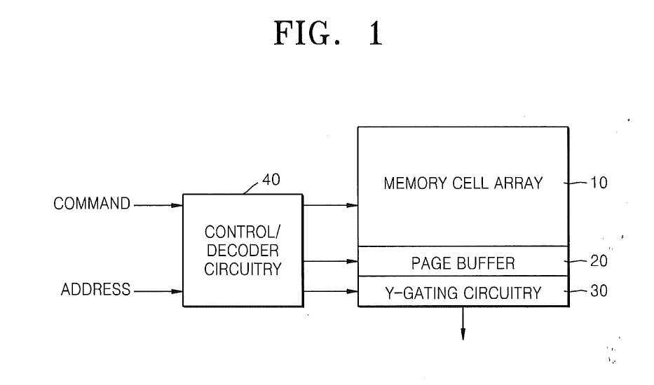

FIG. 1 is a block diagram of a non-volatile memory device according to an embodiment of the inventive concept. Referring to FIG. 1, the non-volatile memory device may include a memory cell array 10, a page buffer 20, a Y-gating circuitry 30, and a control/decoder circuitry 40.

The memory cell array 10 may include a plurality of memory blocks, and each of the plurality of memory blocks may include a plurality of non-volatile memory cells. Here, the non-volatile memory cells may be flash memory cells, and more particularly, be NAND flash memory cells or NOR flash memory cells. The page buffer 20 may temporarily store data to be written to the memory cell array 10 or data to be read out from the memory cell array 10. The Y-gating circuitry 30 may transmit data stored in the page buffer 20. The control/decoder circuitry 40 may receive an external input of a command or an address, may output a control signal for writing data to the memory cell array 10 or reading out data from the memory cell array 10, and may decode the address. Furthermore, the control/decoder circuitry 40 may output a control signal for writing/reading data to/from the page buffer 20 and may provide address information to the Y-gating circuitry 30.

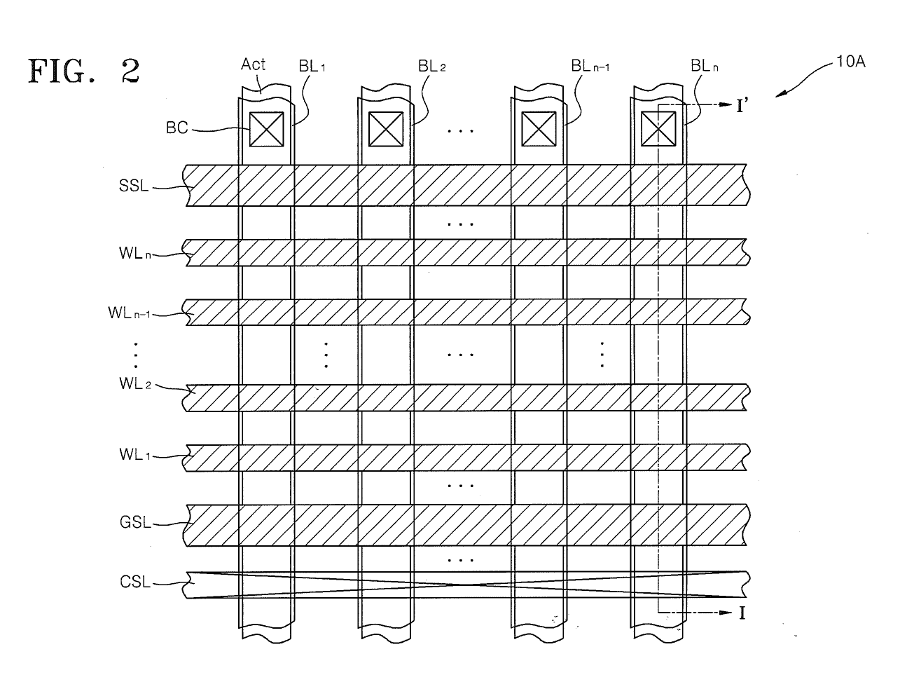

FIG. 2 is a layout diagram of a portion of the memory cell array 10A included in the non-volatile memory device of FIG. 1, according to an embodiment of the inventive concept.

Referring to FIG. 2, the memory cell array 10A may include a plurality of active regions Act that are defined by device isolation regions foamed in a semiconductor layer. A string selection line SSL and a ground selection line GSL may be disposed in a direction across the plurality of active regions Act. First through nth word lines WL1, WL2, . . . , WLn−1, and WLn may be disposed between the string selection line SSL and the ground selection line GSL. In some embodiments, the string selection line SSL, the ground selection line GSL, and the plurality of word lines plurality of word lines WL1, WL2, . . . , WLn−1, and WLn may be parallel to each other. Impurity regions may be formed in portions of the active regions Act adjacent to both sides of the string selection line SSL, the ground selection line GSL, and the plurality of word lines WL1, WL2, . . . , WLn−1, and WLn. Therefore, a string selection transistor, a plurality of cell transistors, and a ground selection transistor, which are connected in series, may be formed. The string selection transistor, the plurality of cell transistors, and the ground selection transistor may form one unit memory block. As described above, a non-volatile memory device according to the embodiments of FIG. 2 may include NAND flash memory cells. However, the inventive concept is not limited thereto.

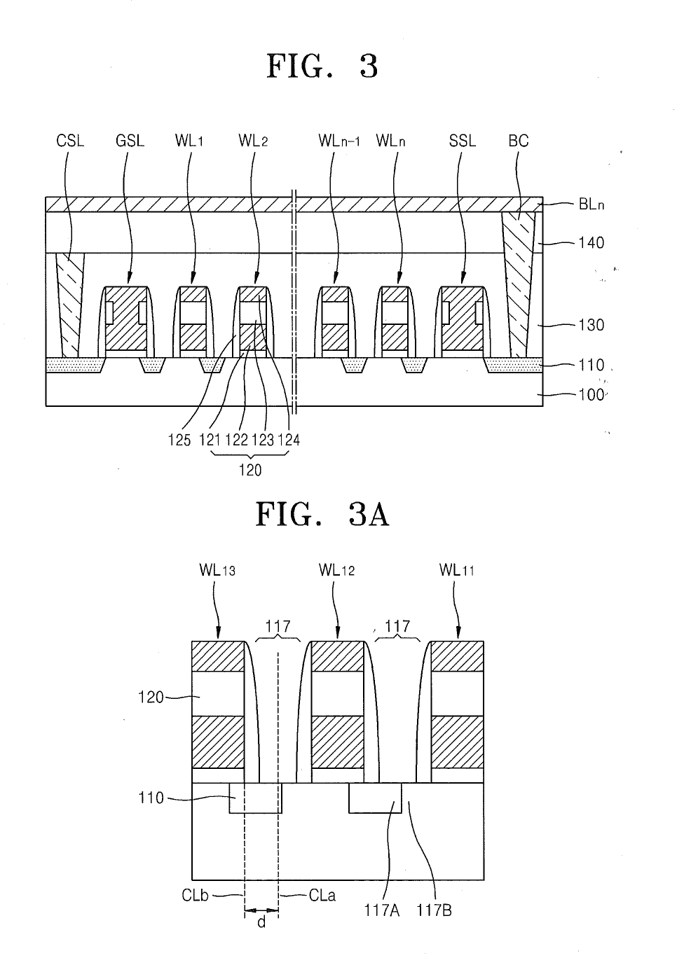

FIG. 3 is a sectional view of a cell string according to some embodiments of the inventive concept, the sectional view obtained along a line I-I′ of FIG. 2.

Referring to FIG. 3, the cell string includes the plurality of cell transistors, the string selection transistor, and the ground selection transistor, which are formed on a substrate 100, wherein the string selection transistor, the plurality of cell transistors, and the ground selection transistor may be connected to each other in series.

The substrate 100 may include a plurality of first regions on which gate structures 120 are formed, and a plurality of second regions, wherein the plurality of first regions and the plurality of second regions are alternately arranged. In other words, a second region refers to a region between each two adjacent gate structures 120 on the substrate 100. Here, the substrate 100 may be a semiconductor substrate, wherein the semiconductor substrate may include silicon, silicon-on-insulator, silicon-on-sapphire, germanium, silicon-germanium, or gallium-arsenide. According to the embodiments of FIG. 3, the substrate 100 may be a p-type semiconductor substrate.

Each of the plurality of gate structures 120, which respectively correspond to the first through nth word lines WL1, WL2, . . . , WLn−1, and WLn, may include a tunneling insulation layer 121, a charge storage layer 122, an interlayer insulation layer 123, and a gate electrode layer 124, which are sequentially stacked in the stated order on the substrate 100. Furthermore, although not shown, each of the plurality of word lines WL1, WL2, . . . , WLn−1, and WLn may further include a barrier conductive layer and/or a word line conductive layer on the gate electrode layer 124.

The tunneling insulation layer 121 may be a single layer or a multi-layer, including one or more from among silicon oxide (SiO₂), silicon nitride (Si₃N₄), silicon oxynitride (SiON), hafnium oxide (HfO₂), hafnium silicon oxide (HfSiₓO_{y}), aluminum oxide (Al₂O₃), and zirconium oxide (ZrO₂).

The charge storage layer 122 may be a charge trapping layer or a floating gate conductive layer. In the case where the charge storage layer 122 is a charge trapping layer, the charge storage layer 122 may be a single layer or a multi-layer, including one or more from among SiO₂, Si₃N₄, SiON, HfP₂, ZrO₂, tantalum oxide (Ta₂O₃), titanium oxide (TiO₂), hafnium aluminum oxide (HfAlₓO_{y}), hafnium tantalum oxide (HfTaₓO_{y}), HfSiₓO_{y}, aluminum nitride (AlₓN_{y}), and aluminum gallium nitride (AlGaₓN_{y}). On the other hand, in the case where the charge storage layer 122 is a floating gate conductive layer, the charge storage layer 122 may be formed by depositing poly-silicon through a chemical vapor deposition (CVD), e.g., low pressure CVD (LPCVD) using Sin₂ or Si₂H₆ and PH₃ gas.

The interlayer insulation layer 123 may be a single layer or a multi-layer, including one or more from among SiO₂, Si₃N₄, SiON, and a high-k material. Here, the high-k material may include at least one from among Al₂O₃, Ta₂O₃, TiO₂, yttrium oxide (Y₂O₃), ZrO₂, zirconium silicon oxide (ZrSiₓO_{y}), HfO₂, HfSiₓO_{y}, lanthanum oxide (La₂O₃), lanthanum aluminum oxide (LaAlₓO_{y}), lanthanum hafnium oxide (LaHfₓO_{y}), HfAlₓO_{y}, and praseodymium oxide (Pr₂O₃). Here, the interlayer insulation layer 123 may also be referred to as a blocking insulation layer.

The gate electrode layer 124 may be a single layer or a multi-layer, including one or more from among poly-silicon, aluminum (Al), gold (Au), beryllium (Be), bismuth (Bi), cobalt (Co), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), zirconium (Zr), nitrides thereof, and silicides thereof.

A spacer 125 may be formed on sidewalls of the tunneling insulation layer 121, the charge storage layer 122, the interlayer insulation layer 123, and the gate electrode layer 124. The spacer 125 may be formed of a plurality of layers. The structures of the tunneling insulation layer 121, the charge storage layer 122, the interlayer insulation layer 123, and the gate electrode layer 124 described above are merely examples, and the inventive concept is not limited thereto.

The gate structures 120 connected to the string selection line SSL and the ground selection line GSL may have the same stack structure as the gate structures 120 connected to the word lines WL1, WL2, . . . , WLn−1, and WLn, as described above. Alternatively, the gate structures 120 connected to the string selection line SSL and the ground selection line GSL may have the same stack structure as that of the gate structures 120 connected to the word lines WL1, WL2, . . . , WLn−1, and WLn, except that the interlayer insulation layer 123 may be partially removed as shown. Generally, the width of the gate structures 120 connected to the string selection line SSL and the ground selection line GSL may be greater than the width of the gate structures 120 connected to the word lines WL1, WL2, . . . , WLn−1, and WLn. However, the inventive concept is not limited thereto.

A plurality of impurity regions 110 may be formed in the substrate 100, for example, through an ion implantation. Each of the plurality of impurity regions 110 may have a shape that is symmetrical or substantially symmetrical with respect to a vertical axis running through its center. The plurality of impurity regions 110 may be source/drain regions of the plurality of cell transistors, the ground selection transistor, and the string selection transistor. For example, the impurity regions 110 formed on the left of each of the word lines WL1, WL2, . . . , WLn−1, and WLn may be the source regions of cell transistors, whereas the impurity regions 110 formed on the right of each of the word lines WL1, WL2, . . . , WLn−1, and WLn may be the drain regions of the cell transistors. Furthermore, the impurity region 110 formed on the left of the ground selection line GSL may be the source region of the ground selection transistor, whereas the impurity region 110 formed on the right of the ground selection line GSL may be the drain region of the ground selection transistor. Furthermore, the impurity region 110 formed on the left of the string selection line SSL may be the source region of the string selection transistor, whereas the impurity region 110 formed on the right of the string selection line SSL may be the drain region of the string selection transistor. Here, the terms “left” and “right” are merely used for convenience of explanation, and directions indicated thereby may be reversed.

The programming operation on the cell string may be performed from a cell transistor closest to the string selection line SSL to a cell transistor closest to the ground selection line GSL. In other words, a programming voltage may be applied to from the word line WLn closest to to a bit line contact plug BC to the word line WL1 closest to a common source line CSL. Therefore, in two adjacent gate structures 120, the potential of the charge storage layer 122 included in the gate structure 120 closer to the bit line contact plug BC is changed first, and thus the potentials of the channel region and the drain region of the other gate structure 120 may be changed second. For example, if the potential of the charge storage layer 122 included in the gate structure 120 connected to the word line WL2 is changed, the potentials of the channel region and the drain region of the gate structure 120 connected to the first word line WL1 are changed.

In the embodiments illustrated in FIG. 3, centers of the impurity regions 110 formed between the word lines WL1, WL2, . . . , WLn−1, and WLn may be horizontally offset (relative to the orientation of the substrate 100) by a predetermined distance from centers of the second regions of the substrate 100, respectively, toward the common source line CSL. In other words, each of the impurity regions 110 formed between word lines WL1, WL2, . . . , WLn−1, and WLn may be offset by a predetermined distance toward one of two word lines, such as the word line closer to the common source line CSL. Therefore, the impurity regions 110 may be formed in portions of the substrate 100, which are between the gate structures 120 and below the gate structures 120, i.e., portions of the first region and the second region, and thus the centers of each of the impurity regions 110 may not be vertically aligned (relative to the orientation of the substrate 100) with the respective centers of regions between the adjacent two gate structures 120, i.e., the centers of the second regions, as illustrated in FIG. 3.

For example, referring to FIG. 3A, a center CLb of an impurity region 110 may be horizontally offset from a center CLa of a second region 117 between two neighboring gate structures 120 by a distance d. Accordingly, portions of the impurity region 110 may be located at least partially beneath one of the gate structures 120. Moreover, the substrate may be doped with second conductivity type impurities (e.g. p-type impurities) while the impurity regions 110 may be doped by implanting first conductivity type impurities (e.g. n-type impurities) into the substrate 100. Thus, a first sub-region 117A of the second region 117 between adjacent gate structures 120 may be doped with both first and second conductivity type dopants with a net conductivity of the first conductivity type, while a second sub-region 117B may be doped only with second conductivity type dopants.

In some embodiments, a width of the second region between neighboring gate structures 120 may be less than about 30 nm, and the distance d by which the center of an impurity region 110 is horizontally offset from the center of the second region may be less than about 15 nm. The width of the second region between neighboring gate structures 120 may be controlled based on a design rule of word lines. As will be apparent from the discussion below, the distance d may be dependent on factors such as the heights of the gate structures 120, an angle at which impurities are implanted into the substrate 100 to form the impurity regions 110, and/or the number and conductivity type of the implants.

As described above, as the impurity regions 110 between the word lines WL1, WL2, . . . , WLn−1, and WLn are located a predetermined distance from the second regions of the substrate 100 toward the common source line CSL, the coupling ratio between the charge storage layer 122 of a cell transistor connected to the word line WL2 and the charge storage layer 122 of a cell transistor connected to the first word line WL1 may be reduced, for example. In some cases, the coupling ratio between the charge storage layer 122 of a cell transistor connected to the word line WL2 and the charge storage layer 122 of a cell transistor connected to the first word line WL1 in the case where the center of each of the impurity regions 110 overlaps the center of the second region may be approximately 0.25, whereas the coupling ratio between the charge storage layer 122 of a cell transistor connected to the word line WL2 and the charge storage layer 122 of a cell transistor connected to the first word line WL1 in the case where the center of each of the impurity regions 110 is horizontally offset by a predetermined distance toward the common source line CSL and the center of each of the impurity regions 110 does not overlap the center of the second region may be approximately 0.16. Therefore, the effect of a variation of the potential of the charge storage layer 122 of a cell transistor connected to the word line WL2 on the channel region of a cell transistor connected to the first word line WL1 may be reduced, and thus the variation of the threshold voltage of the cell transistor connected to the first word line WL1 may be reduced.

In the embodiments of FIG. 3, the impurity regions 110 formed between the word lines WL1, WL2, . . . , WLn−1, and WLn may be formed through an angled ion implantation, in which an impurity is injected in a direction inclined by a predetermined angle from a direction vertical to the substrate 100. At this point, the angled ion implantation may be performed in a direction inclined toward the bit line contact plug BC by a predetermined angle from a direction vertical to the substrate 100. For example, the predetermined angle may be from about 5° to about 10°. The impurity regions 110 corresponding to the source region of the ground selection line GSL and the drain region of the string selection line SSL may be formed by performing an ion implantation in a direction vertical to the substrate 100. In the present embodiment, the impurity may be an n-type impurity, such as phosphorous (P), arsenic (As), antimony (Sb), or the like.

A first interlayer insulation layer 130 may be formed on the top surface of the substrate 100, and may cover the word lines WL1, WL2, . . . , WLn−1, and WLn, the string selection line SSL, and the ground selection line GSL. The common source line CSL may penetrate the first interlayer insulation layer 130 and may be connected to the source region of the ground selection transistor connected to the ground selection line GSL. The common source line CSL may be formed to be parallel to the ground selection line GSL.

A second interlayer insulation layer 140 may be formed on the first interlayer insulation layer 130. The bit line contact plug BC may penetrate the second interlayer insulation layer 140 and the first interlayer insulation layer 130 and may be connected to the drain region of the string selection transistor connected to the string selection line SSL. A bit line BLn may be formed on the second interlayer insulation layer 140. The bit line BLn may be connected to the bit line contact plug BC, and may extend across over the word lines WL1, WL2, . . . , WLn−1, and WLn. The bit line BLn may be formed to be parallel to the active regions Act.

According to other embodiments of the inventive concept, the impurity regions 110 between the word lines WL1, WL2, . . . , WLn−1, and WLn may be horizontally offset by a predetermined distance from the centers of the second regions of the substrate 100 toward the bit line contact plug BC. Furthermore, according to other embodiments of the inventive concept, each of the impurity regions 110 may have a shape that is asymmetrical or substantially asymmetrical with respect to a vertical axis running through its center.

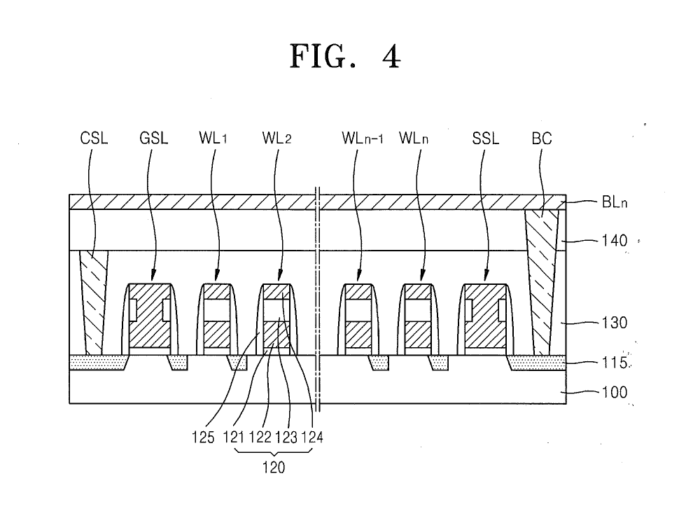

FIG. 4 is a sectional view of a cell string according to further embodiments of the inventive concept, the sectional view obtained along a line I-I′ of FIG. 2.

Referring to FIG. 4, the cell string includes a plurality of cell transistors, a string selection transistor, and a ground selection transistor, which are formed on the substrate 100, and the plurality of cell transistors, the string selection transistor, and the ground selection transistor may be connected to each other in series. The cell string shown in FIG. 4 has a structure similar to that of the cell string shown in FIG. 3, and thus the same descriptions will be omitted. The descriptions above with respect to the cell string of FIG. 3 may apply to the cell string according to the present embodiment.

For example, a plurality of impurity regions 115 may be formed in the substrate 100 through an ion implantation. Each of the plurality of impurity regions 115 may have a shape that is asymmetrical or substantially asymmetrical with respect to a vertical axis running through its center. The plurality of impurity regions 115 may correspond to source/drain regions of the plurality of cell transistors, the ground selection transistor, and the string selection transistor

In the embodiments of FIG. 4, the impurity regions 115 formed between the word lines WL1, WL2, . . . , WLn−1, and WLn may be formed in the second regions of the substrate 100 to be closer to the common source line CSL. In other words, each of the impurity regions 115 formed between word lines WL1, WL2, . . . , WLn−1, and WLn may be formed to be closer to one of two word lines, such as the word line closer to the common source line CSL. Therefore, the impurity regions 115 may be formed in portions of the substrate 100, which are between the gate structures 120 and below the gate structures 120, i.e., portions of the first region and the second region, and thus the centers of the impurity regions 115 may not be vertically aligned with the centers of the regions between adjacent two gate structures 120, i.e., the centers of the second regions.

As described above, because each of the impurity regions 115 between the word lines WL1, WL2, . . . , WLn−1, and WLn may be formed to be closer to one of two word lines, such as the word line closer to the common source line CSL, the coupling ratio between the charge storage layer 122 of a cell transistor connected to the word line WL2 and the charge storage layer 122 of a cell transistor connected to the neighboring word line WL1 may be reduced, for example. Therefore, the effect of a variation of the potential of the charge storage layer 122 of a cell transistor connected to the word line WL2 on the channel region of a cell transistor connected to the first word line WL1 may be reduced, and thus the variation of the threshold voltage of the cell transistor connected to the first word line WL1 may be reduced.

In the embodiments of FIG. 4, the impurity regions 115 formed between the word lines WL1, WL2, . . . , WLn−1, and WLn may be formed by performing an ion implantation of a first conductivity type impurity in a direction vertical to the substrate 100 and performing an angled ion implantation of a second conductivity type impurity in a direction inclined by a predetermined angle from a direction vertical to the substrate 100. At this point, the angled ion implantation may be performed toward the common source line CSL in a direction inclined toward the common source line CSL by a predetermined angle from a direction vertical to the substrate 100. For example, the predetermined angle may be from about 5° to about 10°. The impurity regions 115 corresponding to the source region of the ground selection line GSL and the drain region of the string selection line SSL may be formed by performing an ion implantation of a first conductivity type impurity in a direction vertical to the substrate 100. In the embodiments of FIG. 4, a first conductivity type impurity may be an n-type impurity, such as P, As, Sb, or the like, whereas a second conductivity type impurity may be a p-type impurity, such as boron (B), gallium (Ga), In, or the like.

Accordingly, referring again to FIG. 3B and FIG. 4, in the embodiments of FIG. 4, a first sub-region 117A of the second region 117 between adjacent gate structures 120 may be doped with both first and second conductivity type dopants with a net conductivity of the first conductivity type, while a second sub-region 117B may be doped with both first and second conductivity type dopants with a net conductivity of the second conductivity type.

According to other embodiments of the inventive concept, centers of the impurity regions 115 between the word lines WL1, WL2, . . . , WLn−1, and WLn may be horizontally offset by a predetermined distance from the centers of the second regions of the substrate 100 toward the bit line contact plug BC. Furthermore, according to other embodiments of the inventive concept, each of the impurity regions 115 may have a shape that is symmetrical or substantially symmetrical with respect to a vertical axis running through its center.

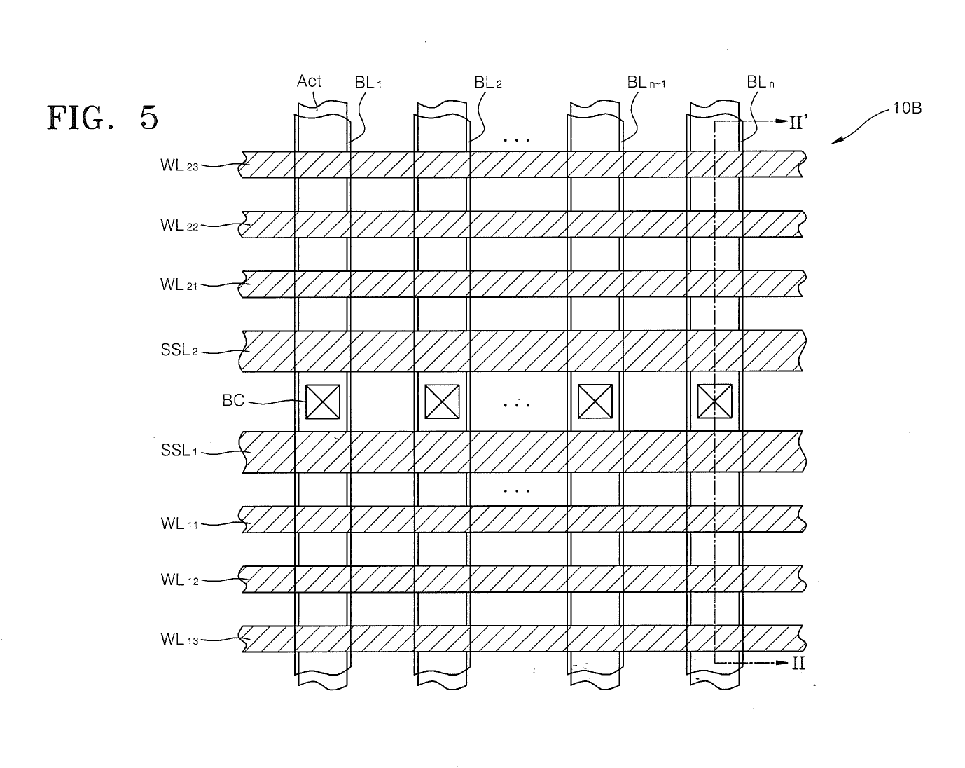

FIG. 5 is a layout diagram of a portion of a memory cell array 10B included in the non-volatile memory device of FIG. 1, according to further embodiments of the present invention.

Referring to FIG. 5, the memory cell array 10B may include the plurality of active regions Act that are defined in device isolation regions formed in a semiconductor layer. A plurality of bit lines BL1, BL2, . . . , BLn−1, and BLn may be formed on the plurality of active regions Act. The plurality of active regions Act may be respectively connected to the plurality of bit lines BL1, BL2, . . . , BLn−1, and BLn via corresponding bit line contact plugs BC. A first string selection line SSL1 and word lines WL11, WL12, and WL13 may be formed to be parallel to each other on a first side of the bit line contact plugs BC in a direction across the plurality of active regions Act. Impurity regions may be formed in the active regions Act adjacent to both sides of the first string selection line SSL1 and the first through third word lines WL11, WL12, and WL13. Therefore, a string selection transistor and cell transistors, which are connected to each other in series, may be formed, and the string selection transistor and the cell transistors may form a first memory block together with a ground selection transistor (not shown). Furthermore, a second string selection line SSL2 and word lines WL21, WL22, and WL23 may be formed to be parallel to each other on a second side of the bit line contact plugs BC in a direction across the plurality of active regions Act. Impurity regions may be formed in the active regions Act adjacent to both sides of the second string selection line SSL2 and the fourth through sixth word lines WL21, WL22, and WL23. Therefore, a string selection transistor and cell transistors, which are connected to each other in series, may be formed, and the string selection transistor and the cell transistors may form a second memory block together with a ground selection transistor (not shown). As described above, the first memory block and the second memory block may be mirror structures with respect to the bit line contact plugs BC.

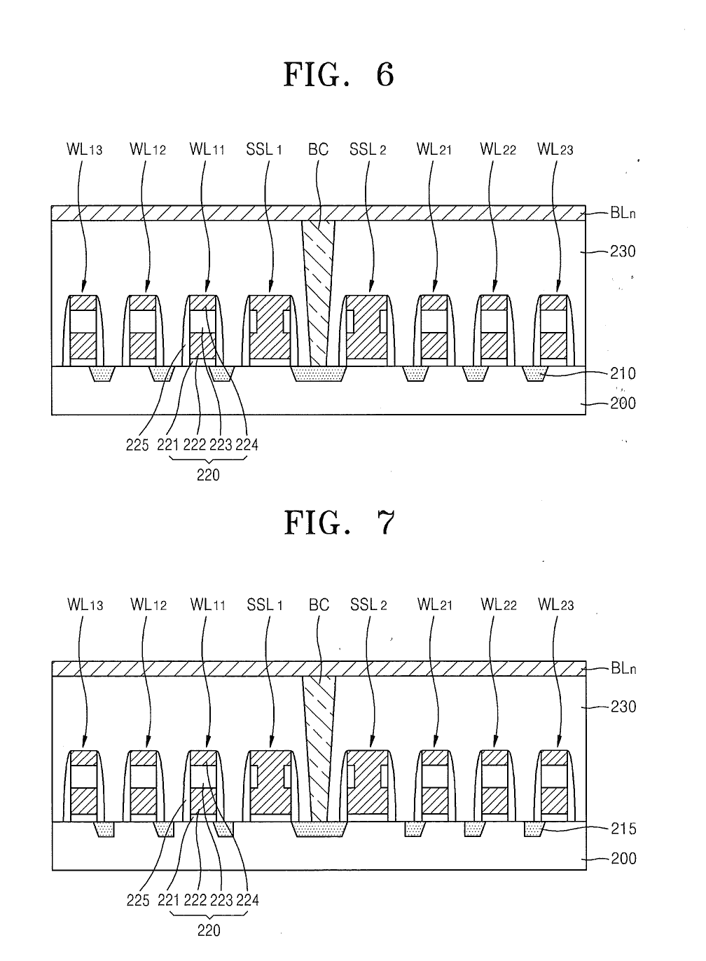

FIG. 6 is a sectional view of a cell string according to an embodiment of the inventive concept, the sectional view obtained along a line II-II′ of FIG. 5.

Referring to FIG. 6, the cell string may include string selection transistors and a plurality of cell transistors, which are formed on a substrate 200 to be on two opposite sides of the bit line contact plugs BC. The cell string shown in FIG. 6 is similar to the cell string shown in FIG. 3, and thus the same descriptions will be omitted. The descriptions above with respect to the cell string of FIG. 3 may apply to the cell string according to the present embodiment.

The substrate 200 may be divided into a first memory block region at a first side of the bit line contact plug BC and a second memory block region at a second side of the bit line contact plug BC. The first string selection line SSL1 and the first through third word lines WL11, WL12, and WL13 may be formed in the first memory block region, whereas the second string selection line SSL2 and the fourth through sixth word lines WL21, WL22, and WL23 may be formed in the second memory block region. Furthermore, the substrate 200 may include a plurality of first regions on which gate structures 220 are formed, and a plurality of second regions, wherein the plurality of first regions and the plurality of second regions are arranged in an alternating fashion. In other words, a second region refers to a region between two adjacent gate structures 220 on the substrate 200.

The plurality of gate structures 220 respectively connected to the first through sixth word lines WL11, WL12, WL13, WL21, WL22, and WL23 may each include a tunneling insulation layer 221, a charge storage layer 222, an interlayer insulation layer 223, and a gate electrode layer 224, which are sequentially stacked in the stated order on the substrate 200. Furthermore, although not shown, each of the first through sixth word lines WL11, WL12, WL13, WL21, WL22, and WL23 may further include a barrier conductive layer and/or a word line conductive layer on the gate electrode layer 224. Furthermore, a spacer 225 may be formed on sidewalls of the tunneling insulation layer 221, the charge storage layer 222, the interlayer insulation layer 223, and the gate electrode layer 224.

A plurality of impurity regions 210 may be formed in the substrate 200 through an ion implantation. Each of the plurality of impurity regions 210 may have a shape that is symmetrical or substantially symmetrical with respect to a vertical axis running through its center. The plurality of impurity regions 210 may be source/drain regions of the plurality of cell transistors, a ground selection transistor, and string selection transistors.

The programming operation on the cell string may be performed from a cell transistor closest to a string selection line SSL1, SSL2. In other words, a programming voltage may be applied to from the first word line WL11 closest to a first side of the bit line contact plug BC to the word line WL13, and a programming voltage may be applied to from the fourth word line WL21 close to a second side of the bit line contact plug BC to the sixth word line WL23. Therefore, in two of the adjacent gate structures 220, the potential of the charge storage layer 222 included in the gate structure 220 closer to the bit line contact plug BC is changed first, and thus the potentials of the channel region and the drain region of the other gate structure 220 are changed second.

In the embodiments of FIG. 6, centers of the impurity regions 210 formed between the first string selection line SSL1 and the first through third word lines WL11, WL12, and WL13 may be horizontally offset by a predetermined distance from the respective centers of the second regions of the substrate 200, respectively, toward the third word line WL13. In other words, each of the impurity regions 210 formed between the first string selection line SSL1 and the first through third word lines WL11, WL12, and WL13 may be horizontally offset by a predetermined distance toward one of two word lines, such as the left word line. In some embodiments, the impurity regions 210 may be formed in portions of the substrate 200, which are between the gate structures 220 and at least partially below the gate structures 220, that is, portions of the first region and the second region, and thus the center of each of the impurity regions 210 may not be vertically aligned with the center of a respective region between the gate structures 220, that is, the center of the respective second region.

Furthermore, centers of the impurity regions 210 formed between the second string selection line SSL2 and the fourth through sixth word lines WL21, WL22, and WL23 may be horizontally offset by a predetermined distance from respective centers of the second regions of the substrate 200, respectively, toward the sixth word line WL23. In other words, each of the impurity regions 210 formed between the second string selection line SSL2 and the fourth through sixth word lines WL21, WL22, and WL23 may be horizontally offset by a predetermined distance toward one of two word lines, such as the right word line. Therefore, the impurity regions 210 may be formed in portions of the substrate 200, which are between the gate structures 220 and at least partially below the gate structures 220. Thus, portions of the first region and the second region, and thus the center of each of the impurity regions 210 may not be vertically aligned with the center of a region between the gate structures 220, that is, the center of the second region.

As described above, because each of the impurity regions 210 between the first through sixth word lines WL11, WL12, WL13, WL21, WL22, and WL23 is located a predetermined distance to sides opposite to the bit line contact plug BC, the coupling ratio between the charge storage layer 222 of a cell transistor connected to the first word line WL11 and the charge storage layer 222 of a cell transistor connected to the second word line WL12 may be reduced. Therefore, the effect of a variation of the potential of the charge storage layer 222 of a cell transistor connected to the first word line WL11 on the channel region of a cell transistor connected to the second word line WL12 may be reduced, and thus the variation of the threshold voltage of the cell transistor connected to the second word line WL12 may be reduced.

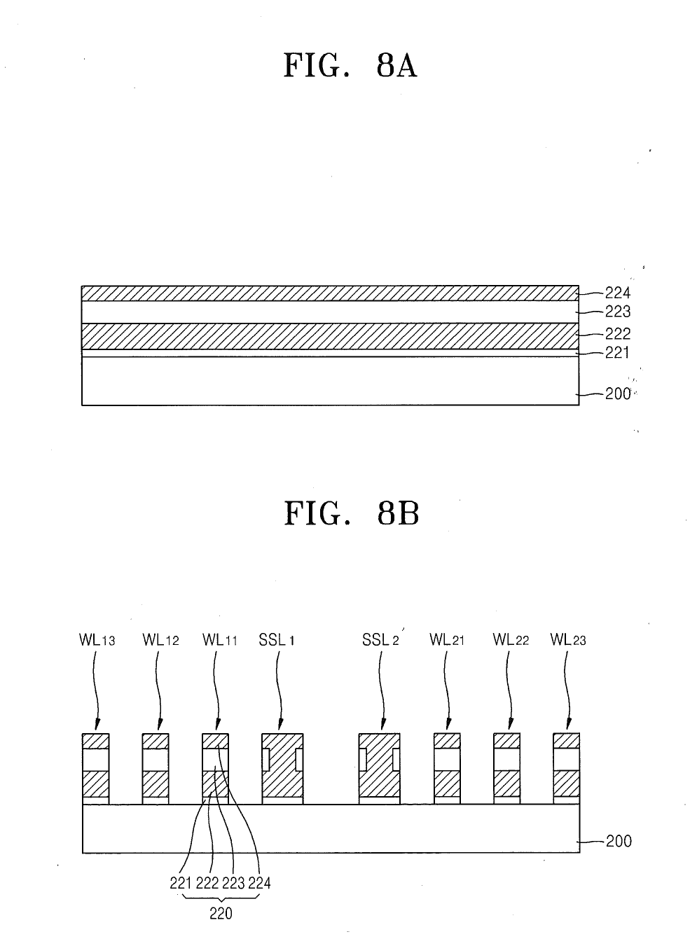

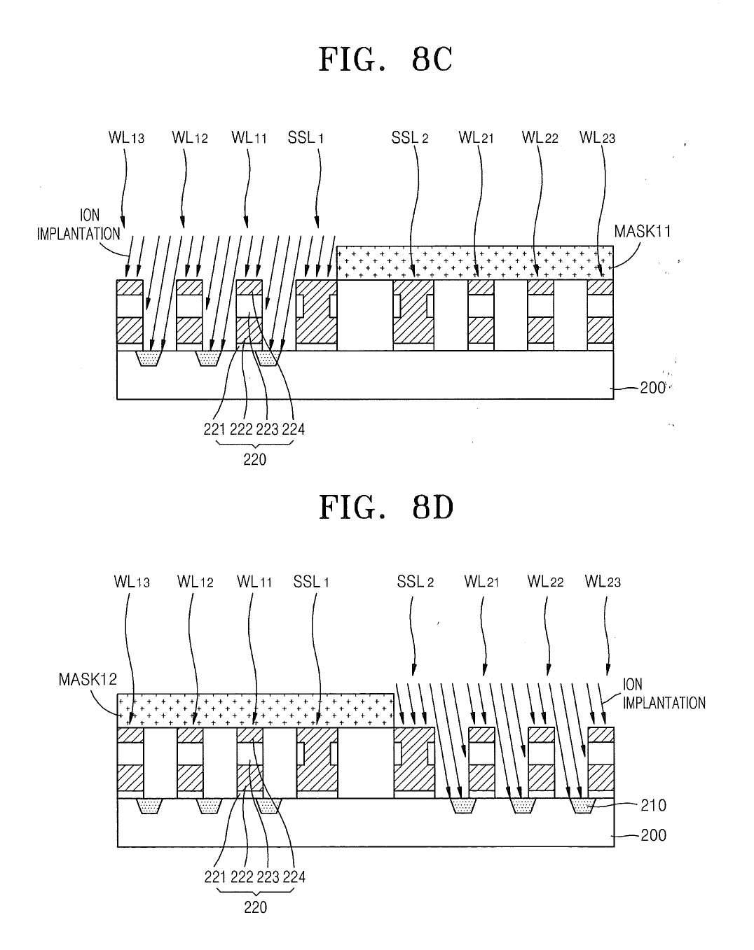

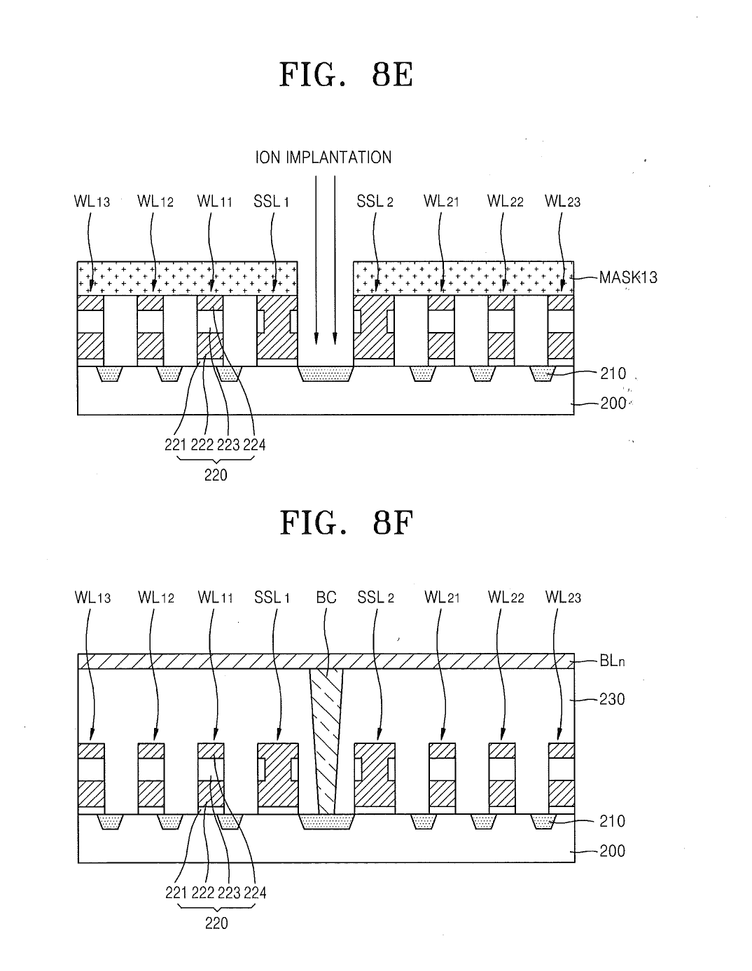

In the embodiments of FIG. 6, the impurity regions 210 formed between the first through sixth word lines WL11, WL12, WL13, WL21, WL22, and WL23 may be formed through an angled ion implantation, in which an impurity is injected in a direction inclined by a predetermined angle from a direction vertical to the substrate 200. Detailed description thereof will be given below with reference to FIGS. 8A through 8F.

An interlayer insulation layer 230 may be formed on the top surface of the substrate 200, and may cover the first through sixth word lines WL11, WL12, WL13, WL21, WL22, and WL23 and the first and second string selection lines SSL1 and SSL2. The bit line contact plug BC may penetrate the interlayer insulation layer 230 and may be interconnected between the first string selection line SSL1 and the second string selection line SSL2. The bit line BLn may be formed on the interlayer insulation layer 230. The bit line BLn may be connected to the bit line contact plug BC, and may extend across over the first through sixth word lines WL11, WL12, WL13, WL21, WL22, and WL23. The bit line BLn may be formed to be parallel to the active regions Act.

According to other embodiments of the inventive concept, the impurity regions 210 between the first through sixth word lines WL11, WL12, WL13, WL21, WL22, and WL23 may be horizontally offset by a predetermined distance toward the bit line contact plug BC. Furthermore, according to other embodiments of the inventive concept, each of the impurity regions 210 may have a shape that is asymmetrical or substantially asymmetrical with respect to a vertical axis running through its center.

FIG. 7 is a sectional view of a cell string according to further embodiments of the inventive concept, the sectional view obtained along a line II-II′ of FIG. 5.

Referring to FIG. 7, the cell string may include string selection transistors cell transistors, which are formed on the substrate 200 to be on two opposite sides of the bit line contact plugs BC. The cell string shown in FIG. 7 has a structure similar to that of the cell string shown in FIG. 6, and thus the same descriptions will be omitted. The descriptions above with respect to the cell string of FIG. 6 may apply to the cell string according to the present embodiment.

For example, a plurality of impurity regions 215 may be formed in the substrate 200 through an ion implantation. Each of the plurality of impurity regions 215 may have a shape that is asymmetrical or substantially asymmetrical with respect to its a vertical axis running through center. The plurality of impurity regions 215 may be source/drain regions of the cell transistors, a ground selection transistor, and string selection transistors.

In the embodiments of FIG. 7, the impurity regions 215 formed between the first string selection line SSL1 and the first through third word lines WL11, WL12, and WL13 may be formed in the second regions of the substrate 100 to be closer to a word line of the first through third word lines WL11, WL12, and WL13, which is farther from the bit line contact plug BC. In other words, each of the impurity regions 215 formed between the first string selection line SSL1 and the first through third word lines WL11, WL12, and WL13 may be formed to be closer to the left one of two adjacent word lines of the first through third word lines WL11, WL12, and WL13. Therefore, the impurity regions 215 may be formed in portions of the substrate 200, which are between the gate structures 220 and below the gate structures 220, that is, portions of the first region and the second region, and thus the centers of the impurity regions 215 may not be vertically aligned with the centers of the regions between the gate structures 220, that is, the centers of the second regions.

Furthermore, the impurity regions 215 formed between the second string selection line SSL2 and the fourth through sixth word lines WL21, WL22, and WL23 may be formed in the second regions of the substrate 200 to be closer to a word line of the first through third word lines WL11, WL12, and WL13, which is farther from the bit line contact plug BC. In other words, each of the impurity regions 215 formed between the second string selection line SSL2 and the fourth through sixth word lines WL21, WL22, and WL23 may be formed be closer to the right one of each two word lines of the first through third word lines WL11, WL12, and WL13. Therefore, the impurity regions 215 may be formed in portions of the substrate 200, which are between the gate structures 220 and below the gate structures 220, that is, portions of the'first region and the second region, and thus the centers of the impurity regions 215 may not be vertically aligned with the centers of the regions between the gate structures 220, that is, the centers of the second regions.

As described above, because each of the impurity regions 215 between the first through sixth word lines WL11, WL12, WL13, WL21, WL22, and WL23 is formed to be closer to one of two word lines, the word line farther from the bit line contact plug BC, the coupling ratio between the charge storage layer 222 of a cell transistor connected to the first word line WL11 and the charge storage layer 222 of a cell transistor connected to the second word line WL12 may be reduced, for example. Therefore, the effect of a variation of the potential of the charge storage layer 222 of a cell transistor connected to the first word line WL11 on the channel region of a cell transistor connected to the second word line WL12 may be reduced, and thus the variation of the threshold voltage of the cell transistor connected to the second word line WL12 may be reduced.

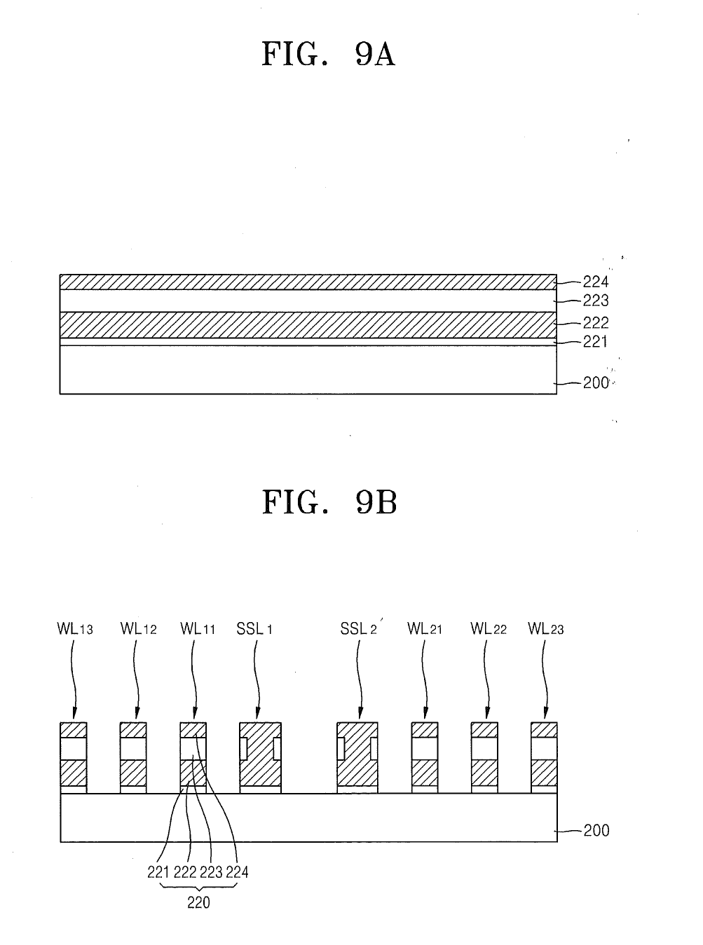

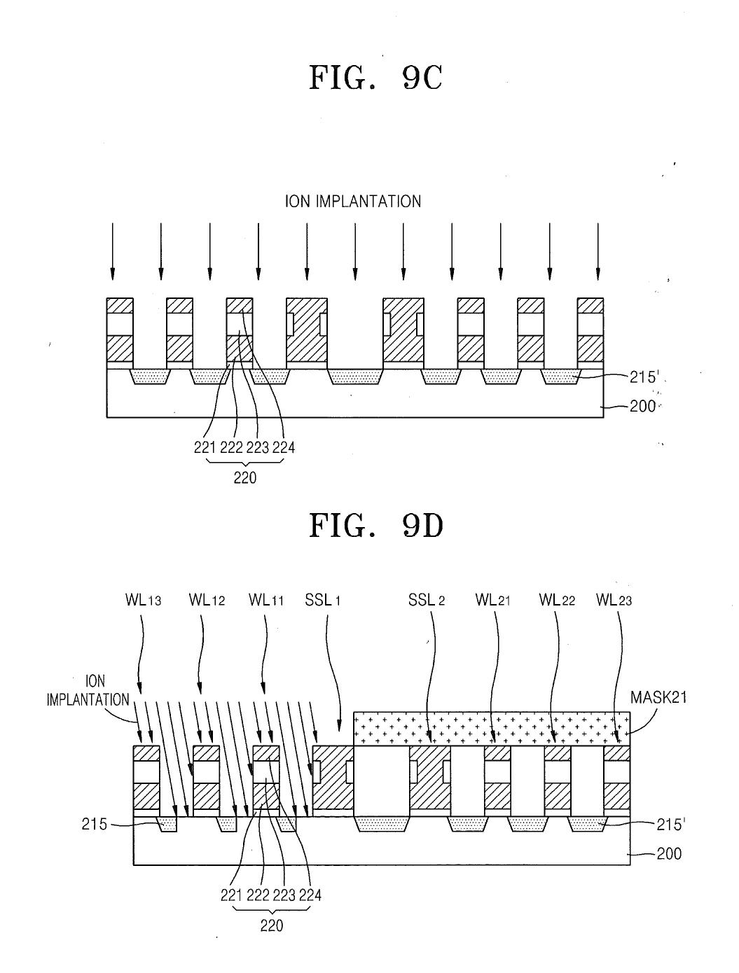

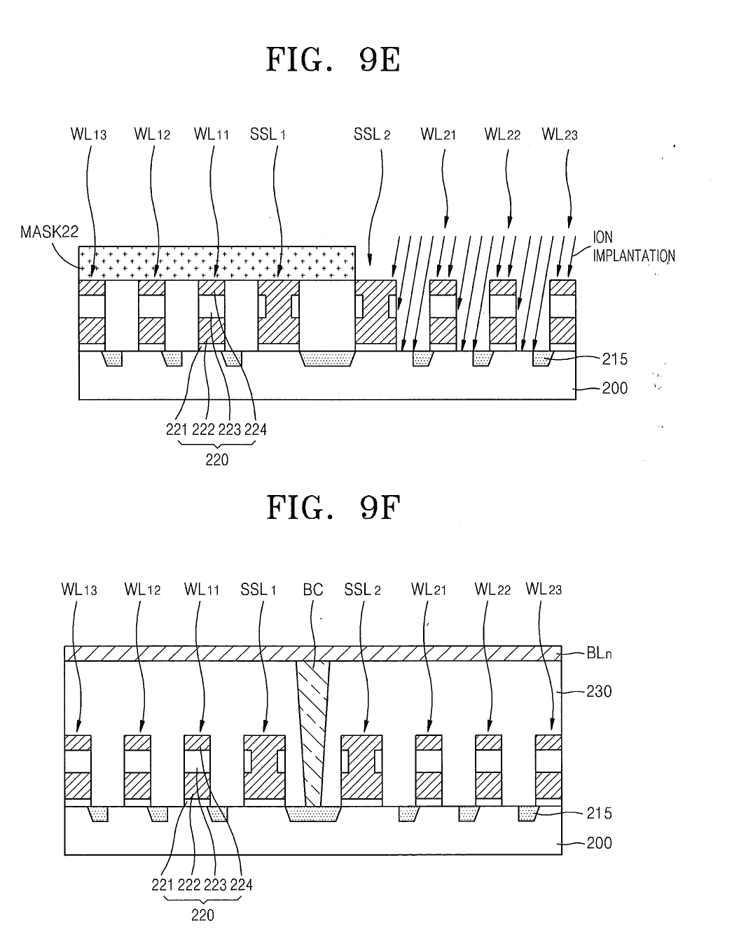

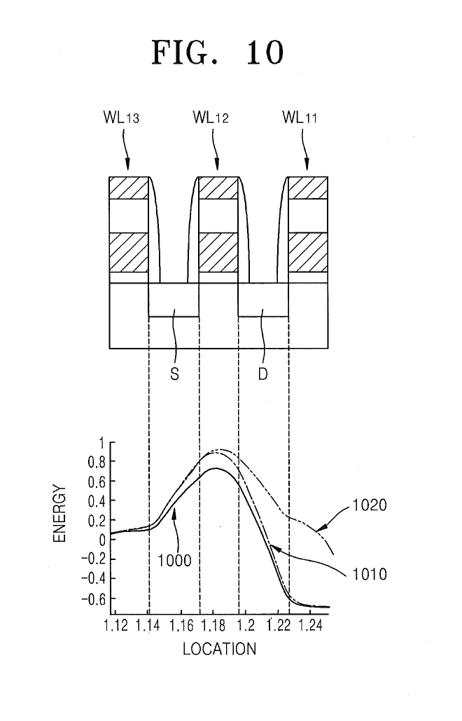

In the embodiments of FIG. 7, the impurity regions 215 formed between the first through sixth word lines WL11, WL12, WL13, WL21, WL22, and WL23 may be formed by performing an ion implantation of a first conductivity type impurity in a direction vertical to the substrate 200 and performing an angled ion implantation of a second conductivity type impurity in a direction inclined by a predetermined angle from a direction vertical to the substrate 200. A detailed description thereof will be given below with reference to FIGS. 9A through 9F

According to other embodiments of the inventive concept, the impurity regions 215 between the first through sixth word lines WL11, WL12, WL13, WL21, WL22, and WL23 may be horizontally offset by a predetermined distance toward the bit line contact plug BC. Furthermore, according to other embodiments of the inventive concept, each of the impurity regions 215 may have a shape that is symmetrical or substantially symmetrical with respect to a vertical axis running through its center.

FIGS. 8A through 8F are sectional views illustrating methods of manufacturing a non-volatile memory device, according to some embodiments of the inventive concept.

Referring to FIG. 8A, the tunneling insulation layer 221, the charge storage layer 222, the interlayer insulation layer 223, and the gate electrode layer 224 are sequentially formed in the stated order on the substrate 200.

Referring to FIG. 8B, to define string selection transistors, ground selection transistors, and cell transistors, an etching mask (not shown) for forming portions at which the string selection transistor, the ground selection transistor, and the cell transistors are to be formed is formed on the top surface of the gate electrode layer 224, and the gate structures 220 are formed by performing an anisotropic etching process, for example.

Referring to FIG. 8C, a first mask layer MASK11 is formed on the second string selection line SSL2 and the fourth through sixth word lines WL21, WL22, and WL23. According to other embodiments of the inventive concept, the first mask layer MASK11 may be foamed on the first and second string selection lines SSL1 and SSL2 and the fourth through sixth word lines WL21, WL22, and WL23. Accordingly, the first mask layer MASK11 may have a margin region between the first string selection line SSL1 and the second string selection line SSL2. At this point, spaces between the second string selection line SSL2 and the fourth through sixth word lines WL21, WL22, and WL23 may be filled with an insulation layer.

Next, the impurity regions 210 are formed in the first memory block by performing angled ion implantation on the first mask layer MASK11. In particular, first conductivity type dopants are injected in a direction inclined to the right by a predetermined angle from a direction vertical to the substrate 200. In some embodiments, the first conductivity type dopants may be n-type dopants. The predetermined angle may be from about 5° to about 10°.

As shown in FIG. 8C, in the first memory block region (i.e., the region that is not covered by the mask MASK11), the substrate 200 is partially shadowed from the implanted impurities by the gate structures 220. However, it will be appreciated that a separate mask could be formed on the gate structures to act as an implant mask in the first memory block region in some embodiments.

Therefore, in the first memory block region, the impurity regions 210 may be horizontally offset to the left from the second regions of the substrate 200 by a predetermined distance d. Because the angled implants are shadowed by the gate structures 220, the distance d by which the impurity regions are horizontally offset may be dependent on the heights of the gate structures 220 and the angle at which impurities are implanted into the substrate 200. In particular, the distance d may be defined by the equation

d=h·tan(θ) (1)

where h is the height of the gate structures 220 and θ is the angle of inclination of the implants from a direction vertical to the substrate 200.

Referring to FIG. 8D, a second mask layer MASK12 is formed on the first string selection line SSL1 and the first through third word lines WL11, WL12, and WL13. According to other embodiments of the inventive concept, the second mask layer MASK12 may be formed on the first and second string selection lines SSL1 and SSL2 and the first through third word lines WL11, WL12, and WL13. Accordingly, the second mask layer MASK12 may have a margin region between the first string selection line SSL1 and the second string selection line SSL2. At this point, spaces between the first string selection line SSL1 and the first through third word lines WL11, WL12, and WL13 may be filled with an insulation layer.

Next, the impurity regions 210 are formed in the second memory block by performing angled ion implantation on the second mask layer MASK12. In detail, first conductivity type dopants are injected in a direction inclined the left by a predetermined angle from a direction vertical to the substrate 200. Here, the first conductivity type dopants may be n-type dopants. The predetermined angle may be from about 5° to about 10°. As shown in FIG. 8D, in the second memory block region (i.e., the region that is not covered by the mask MASK12), the substrate 200 is partially shadowed from the implanted impurities by the gate structures 220. However, it will be appreciated that a separate mask could be formed on the gate structures to act as an implant mask in the first memory block region in some embodiments. Therefore, in the second memory block region, the impurity regions 210 may be horizontally offset to the right from the second regions of the substrate 200 by a predetermined distance

Referring to FIG. 8E, a third mask layer MASK13 is formed on the first and second string selection lines SSL1 and SSL2 and the first through sixth word lines WL11, WL12, WL13, WL21, WL22, and WL23. At this point, spaces between the first and second string selection lines SSL1 and SSL2 and the first through sixth word lines WL11, WL12, WL13, WL21, WL22, and WL23 may be filled with an insulation layer.

Next, the impurity regions 210 is formed between the first and second string selection lines SSL1 and SSL2 by performing an ion implantation on the third mask layer MASK13 in the direction vertical to the substrate 200.

Referring to FIG. 8F, the interlayer insulation layer 230 is formed on the substrate 200, and covers the first and second string selection lines SSL1 and SSL2 and the first through sixth word lines WL11, WL12, WL13, WL21, WL22, and WL23. Next, the bit line contact plug BC is formed in the interlayer insulation layer 230 to be between the first and second string selection lines SSL1 and SSL2. Next, the bit line BLn may be formed on the interlayer insulation layer 230. The bit line BLn may be connected to the bit line contact plug BC and may extend across over the first through sixth word lines WL11, WL12, WL13, WL21, WL22, and WL23.

According to other embodiments of the inventive concept, a spacer may be formed on sidewalls of each of the gate structures 220, prior to the formation of the interlayer insulation layer 230.

FIGS. 9A through 9F are sectional views that illustrate methods of manufacturing a non-volatile memory device according to further embodiments of the inventive concept.

Referring to FIG. 9A, the tunneling insulation layer 221, the charge storage layer 222, the interlayer insulation layer 223, and the gate electrode layer 224 are sequentially formed in the stated order on the substrate 200.

Referring to FIG. 9B, to define string selection transistors, ground selection transistors, and cell transistors, an etching mask (not shown) for forming portions at which the string selection transistor, the ground selection transistor, and the cell transistors are to be formed is formed on the top surface of the gate electrode layer 224, and the gate structures 220 are formed by performing an anisotropic etching process, for example.

Referring to FIG. 9C, preliminary impurity regions 215′ are formed by injecting first conductivity type dopants in a direction vertical to the substrate 200. In some embodiments, the first conductivity type dopants may be n-type dopants.

Referring to FIG. 9D, a first mask layer MASK21 is formed on the second string selection line SSL2 and the fourth through sixth word lines WL21, WL22, and WL23. According to other embodiments of the inventive concept, the first mask layer MASK21 may be formed on the first and second string selection lines SSL1 and SSL2 and the fourth through sixth word lines WL21, WL22, and WL23. Accordingly, the first mask layer MASK21 may have a margin region between the first string selection line SSL1 and the second string selection line SSL2.

Next, second conductivity type dopants are injected on the first mask layer MASK21 in a direction inclined to the left by a predetermined angle from a direction vertical to the substrate 200. In some embodiments, the second conductivity type dopants may be p-type dopants. The predetermined angle may be from about 5° to about 10°. Therefore, portions of the preliminary impurity regions 215′ into which the second conductivity type dopants are injected are electrically neutralized, and thus only portions of the preliminary impurity regions 215′ into which the second conductivity type dopants are not injected remain as the impurity regions 215. Therefore, the impurity regions 215 may be formed to be closer to the left one of two adjacent gate structures 220.

Referring to FIG. 9E, a second mask layer MASK22 is formed on the first string selection line SSL1 and the first through third word lines WL11, WL12, and WL13. According to other embodiments of the inventive concept, the second mask layer MASK22 may be formed on the first and second string selection lines SSL1 and SSL2 and the first through third word lines WL11, WL12, and WL13. Accordingly, the second mask layer MASK22 may have a margin region between the first string selection line SSL1 and the second string selection line SSL2. At this point, spaces between the first string selection line SSL1 and the first through third word lines WL11, WL12, and WL13 may be filled with an insulation layer.

Next, second conductivity type dopants are injected on the second mask layer MASK22 in a direction inclined to the right by a predetermined angle from a direction vertical to the substrate 200. In some embodiments, the second conductivity type dopants may be p-type dopants. The predetermined angle may be from about 5° to about 10°. Therefore, regions of the impurity regions 215, the regions into which the second conductivity type dopants are injected, are electrically neutralized, and thus only regions into which the second conductivity type dopants are not injected remain. Therefore, the impurity regions 215 may be formed to be closer to the right one of two adjacent gate structures 220.

Referring to FIG. 9F, the interlayer insulation layer 230 is formed on the substrate 200, and covers the first and second string selection lines SSL1 and SSL2 and the first through sixth word lines WL11, WL12, WL13, WL21, WL22, and WL23. Next, the bit line contact plug BC is formed in the interlayer insulation layer 230 to be between the first and second string selection lines SSL1 and SSL2. Next, the bit line BLn is formed on the interlayer insulation layer 230. The bit line BLn is connected to the bit line contact plug BC and extends across over the first through sixth word lines WL11, WL12, WL13, WL21, WL22, and WL23.

According to other embodiments of the inventive concept, a spacer may be formed on sidewalls of each of the gate structures 220, prior to the formation of the interlayer insulation layer 230.

FIG. 10 is a graph showing a simulated result of energy levels according to a location on a substrate in a conventional non-volatile memory device.

Referring to FIG. 10, a conventional non-volatile memory device includes gate structures formed on a substrate, and the gate structures may be respectively connected to the first through third word lines WL11, WL12, and WL13. Furthermore, impurity regions, that is, source/drain regions, are formed between each two adjacent gate structures of the gate structures, and thus cell transistors may be formed. In the structure of FIG. 10, the center of each impurity region is vertically aligned with the center of a region between two gate structures. That is, each impurity region is centered in the region between two gate structures. Hereinafter, the effect due to a voltage variation of the first word line WL11 on a lower region of the second word line 12 will be described.

In FIG. 10, the reference numerals 1000, 1010, and 1020 indicate conduction bands according to locations on a substrate.

In FIG. 10, the reference numeral 1000 indicates the potential according to locations on a substrate at the initial state (when no voltage is applied to a cell transistor connected to the first word line WL11). Here, a peak value exists in the channel region of a cell transistor connected to the second word line WL12.

As a voltage is applied to a cell transistor connected to the first word line WL11, the potential of the charge storage layer of the cell transistor may be changed. The reference numeral 1010 indicates the potential according to locations on a substrate in consideration of the effect due to a potential variation of the charge storage layer of the cell transistor connected to the first word line WL11 on the charge storage layer of the cell transistor connected to the second word line WL12. At this point, the shape of the conduction band remains unchanged, whereas the energy barrier between the source region and the drain region rises.

The reference numeral 1020 indicates the potential according to locations on a substrate in consideration of the effect due to a potential variation of the charge storage layer of the cell transistor connected to the first word line WL11 on the channel region of the cell transistor connected to the second word line WL12. At this point, the shape of the conduction band is distorted in the drain region D of the cell transistor connected to the second word line WL12, and thus the threshold voltage may be changed.

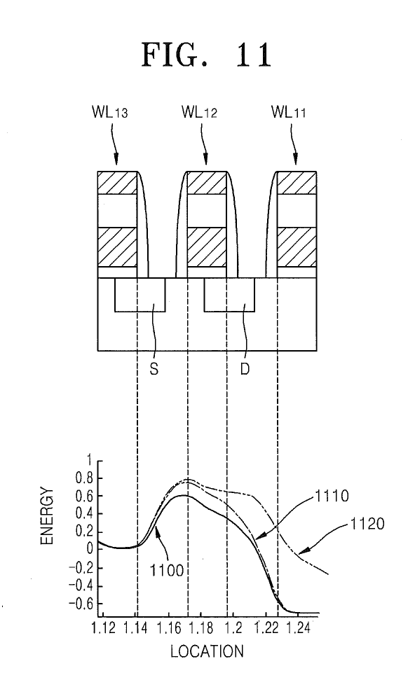

FIG. 11 is a graph showing a simulated result of energy levels according to a location on a substrate in a non-volatile memory device according to an embodiment of the inventive concept.

Referring to FIG. 11, the non-volatile memory device according to the embodiment of the inventive concept includes gate structures formed on a substrate, and the gate structures may be respectively connected to the first through third word lines WL11, WL12, and WL13. Furthermore, impurity regions, that is, source/drain regions are formed between each two adjacent gate structures of the gate structures, and thus cell transistors may be formed. In the structure of FIG. 11, the impurity regions are horizontally offset towards one side of the gate structures by a predetermined distance, and thus the centers of the impurity regions are not vertically aligned with the centers of the regions between adjacent gate structures. The non-volatile memory device may be the non-volatile memory device shown in FIGS. 1 through 9F. Hereinafter, the effect inflicted by a voltage variation of the first word line WL11 to a lower region of the second word line 12 will be described.

In FIG. 11, the reference numerals 1100, 1110, and 1120 indicate conduction bands according to locations on a substrate.

In FIG. 11, the reference numeral 1100 indicates the potential according to locations on a substrate at the initial state (when no voltage is applied to a cell transistor connected to the first word line WL11). Here, a peak value exists to the left of the second word line WL12, that is, the source region of a cell transistor connected to the second word line WL12, and the graph shows relatively large slopes from the peak value to the drain region D.

As a voltage is applied to a cell transistor connected to the first word line WL11, the potential of the charge storage layer of the cell transistor may be changed. The reference numeral 1110 indicates the potential according to locations on a substrate in consideration of the effect due to a potential variation of the charge storage layer of the cell transistor connected to the first word line WL11 on the charge storage layer of the cell transistor connected to the second word line WL12. At this point, the shape of the conduction band remains unchanged, whereas the energy barrier between the source region and the drain region rises.

The reference numeral 1120 indicates the potential according to locations on a substrate in consideration of the effect due to a potential variation of the charge storage layer of the cell transistor connected to the first word line WL11 on the channel region of the cell transistor connected to the second word line WL12. As shown in FIG. 11, since the graph shows relatively small slopes from the peak value to the drain region D, it may not be considered that the energy barrier between the source region and the drain region significantly rises, and thus the variation of the threshold voltage may be reduced. Therefore, the reliability of the non-volatile memory device may be improved.

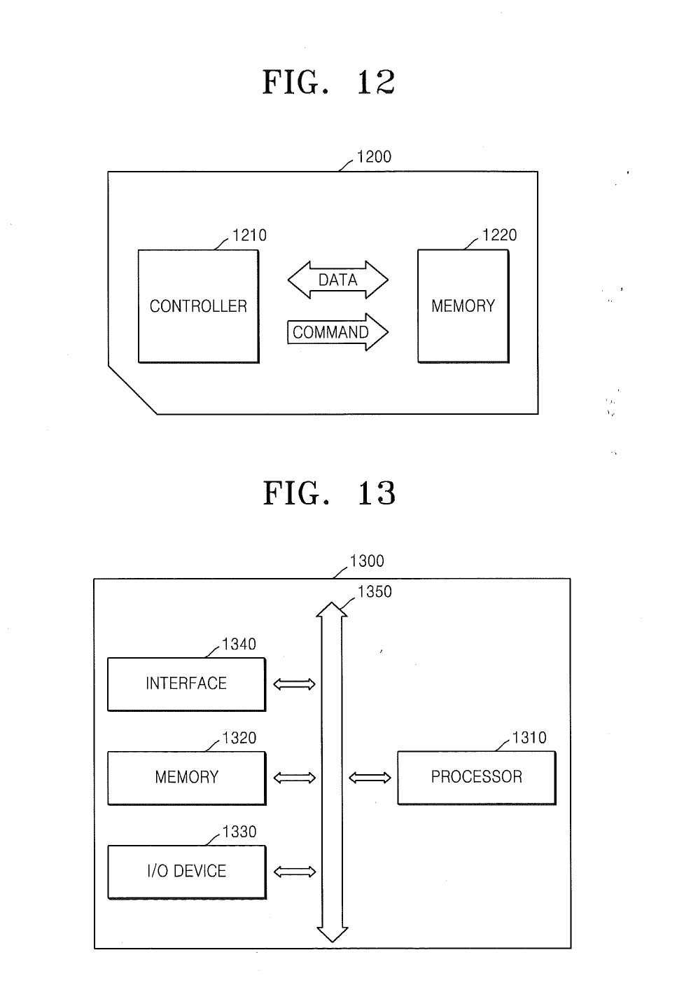

FIG. 12 is a schematic diagram of a card 1200 according to an embodiment of the inventive concept.

Referring to FIG. 12, a controller 1210 and a memory 1220 may be formed to exchange electric signals. For example, when the controller 1210 issues an instruction, the memory 1220 may transmit data. The memory 1220 may include a non-volatile memory device according to any of embodiments of the inventive concept. Non-volatile memory devices according to embodiments of the inventive concept may be formed as “NAND” and “NOR” architecture memory arrays (not shown) in correspondence to corresponding logic gate designs, as known in the art. Memory arrays formed in a plurality of columns and a plurality of rows may form one or more memory array banks (not shown). The memory 1220 may include such a memory array (not shown) or a memory array bank (not shown). Furthermore, the card 1200 may further include a general row decoder (not shown), a general column decoder (not shown), I/O buffers (not shown), and/or a control register (not shown), to drive the memory array bank (not shown). The card 1200 may be used in various card-types of memory devices, e.g., a memory stick card, a smart media (SM) card, a secure digital (SD) card, a mini SD card, and a multimedia card (MMC).

FIG. 13 is a schematic view of an electronic system 1300 according to an embodiment of the inventive concept.

Referring to FIG. 13, the electronic system 1300 may include a processor 1310, a memory 1320, an I/O device 1330, and an interface 1340. The electronic system 1300 may be a mobile system or a system for transmitting/receiving data. The mobile system may be a personal digital assistant (PDA), a portable computer, a web tablet, a wireless phone, a mobile phone, a digital music player, or a memory card.

The processor 1310 may execute a program and control the electronic system 1300. For example, the processor 1310 may be a microprocessor, a digital signal processor, a microcontroller, or the like. The I/O device 1330 may be used to input or output data to/from the electronic system 1300. The electronic system 1300 may be connected to an external device (not shown), e.g., a personal computer or a network, via the I/O device 1330 and may exchange data with the external device. The I/O device 1330 may be a keypad, a keyboard, or a display device, for example. The memory 1320 may store codes and/or data for operating the processor 1310 and/or may store data processed by the processor 1310. The memory 1320 may include a non-volatile memory device according to any of embodiments of the inventive concept. The interface 1340 may be a data transmission path between the electronic system 1300 and the external device. The processor 1310, the memory 1320, the I/O device 1330, and the interface 1340 may communicate with each other via a bus 1350. For example, the electronic system 1300 may be used in a mobile phone, a MP3 player, a navigation device, a portable multimedia player (PMP), a solid state disk (SSD), or a household appliance.

While the inventive concept has been particularly shown and described with reference to exemplary embodiments thereof, it will be understood that various changes in form and details may be made therein without departing from the spirit and scope of the following claims.

1. A non-volatile memory device comprising:
a substrate;
at least two gate structures on the substrate; and
at least one impurity region that is at least partially disposed in a portion of the substrate between the at least two gate structures;
wherein a center of the at least one impurity region is horizontally offset from a center of a region between the at least two gate structures.

2. The non-volatile memory device of claim 1, wherein the at least two gate structures comprise a first gate structure and a second gate structure; and
wherein the first gate structure is configured to receive a programming voltage for performing a programming operation with respect to the non-volatile memory device before the programming voltage is applied to the second gate structure.

3. The non-volatile memory device of claim 2, wherein the center of the at least one impurity region is closer to the second gate structure than the first gate structure.

4. The non-volatile memory device of claim 2, wherein the at least one impurity region is at least partially disposed below the second gate structure.

5. The non-volatile memory device of claim 1, wherein the at least two gate structures comprise a plurality of gate structures arranged in a row on the substrate, wherein the at least one impurity region comprises a plurality of impurity regions, and wherein each of the plurality of impurity regions is between two adjacent gate structures of the plurality of gate structures.

6. The non-volatile memory device of claim 5, further comprising:
a first selection transistor on the substrate and adjacent to the first gate structure of the plurality of gate structures, the first selection transistor being connected to a bit line; and
a second selection transistor on the substrate and adjacent to an N^{th} gate structure of the plurality of gate structures, the second selection transistor being connected to a common source line;
wherein N is in integer equal to or greater than 2.

7. The non-volatile memory device of claim 6, wherein the center of each of the plurality of impurity regions is horizontally offset toward one of two gate structures adjacent to the respective impurity regions that is closer to the second selection transistor.

8. The non-volatile memory device of claim 6, wherein the center of each of the plurality of impurity regions is located horizontally offset toward one of two gate structures adjacent to the respective impurity regions that is closer to the first selection transistor.

9. The non-volatile memory device of claim 1, wherein the at least one impurity region has a shape that is symmetrical with respect to a vertical axis running through the center of the at least one impurity region.

10. The non-volatile memory device of claim 1, wherein the at least one impurity region has a shape that is asymmetrical with respect to a vertical axis running through the center of the at least one impurity region.

11. The non-volatile memory device of claim 1, wherein the at least two gate structures each comprise a tunneling insulation layer on the substrate, a charge storage layer on the tunneling insulation layer, an interlayer insulation layer on the charge storage layer, and a gate electrode layer on the interlayer insulation layer.

12-23. (canceled)

24. A non-volatile memory device comprising:
a semiconductor layer;
a pair of gate structures on the semiconductor layer and defining a region of the semiconductor layer between the pair of gate structures; and
an impurity region in the semiconductor layer, wherein the impurity region is at least partially disposed in the region of the semiconductor layer between the pair of gate structures and comprises a source/drain region for both of the pair of gate structures;
wherein a center of the impurity region is horizontally offset from a center of the region of the semiconductor layer between the pair of gate structures.

25. The non-volatile memory device of claim 24, wherein the impurity region is at least partially disposed beneath a first one of the pair of gate structures.

26. The non-volatile memory device of claim 25, wherein the impurity region does not extend beneath a second one of the pair of gate structures.

27. The non-volatile memory device of claim 24, wherein the semiconductor layer has a first conductivity type; and
wherein the region of the semiconductor layer between the pair of gate structures comprises a first sub-region doped with second conductivity type impurities and a second sub-region that is free of second conductivity type impurities, wherein the second conductivity type is opposite the first conductivity type.

28. The non-volatile memory device of claim 24, wherein the semiconductor layer has a first conductivity type; and
wherein the region of the semiconductor layer between the pair of gate structures comprises a first sub-region doped with first and second conductivity type impurities and that has a net conductivity of the second conductivity type and a second sub-region that is doped with both first and second conductivity type impurities and that has a net conductivity of the first conductivity type, wherein the second conductivity type is opposite the first conductivity type.
